(19) United States
(12) Patent Application Publication
(10) Pub. No.: US 2018/0123013 A1
(43) Pub. Date: May 3, 2018

(54) METAL CORE THERMOELECTRIC DEVICE

(71) Applicant: Phononic Devices, Inc., Durham, NC (US)

(72) Inventors: Brian J. Williams, Chapel Hill, NC (US); Devon Newman, Morrisville, NC (US); Steven Craig Seel, Cary, NC (US)

(21) Appl. No.: 15/798,731

(22) Filed: Oct. 31, 2017

Related U.S. Application Data
(60) Provisional application No. 62/415,223, filed on Oct. 31, 2016.

(51) Int. Cl. H01L 35/04; H01L 27/16; H01L 35/34

(52) U.S. Cl. CPC H01L 35/04; H01L 35/34; H01L 27/16

(57) ABSTRACT

A metal core thermoelectric device and a method of manufacturing such a device are provided herein. In some embodiments, a thermoelectric heat exchanger component includes a metal core circuit board and thermoelectric legs that are attached to the metal core circuit board. A top header is attached to the thermoelectric legs opposite the metal core circuit board. A top heat spreading lid is thermally connected to the top header. In this way, the thermoelectric heat exchanger component does not need the bottom header, bottom side thermal interface material, bottom side attach material, and/or bottom heat spreading lid. This may result in a significant reduction in materials and/or the processing steps required to create the thermoelectric heat exchanger component being greatly simplified. In some embodiments, at least some steps of the manufacturing may use standard surface mount technology equipment.

### RELATED APPLICATIONS

This application claims the benefit of provisional patent application Ser. No. 62/415,223, filed Oct. 31, 2016, the disclosure of which is hereby incorporated herein by reference in its entirety.

### FIELD OF THE DISCLOSURE

The present disclosure relates to thermoelectric devices and their manufacture.

### BACKGROUND

Thermoelectric devices are solid state semiconductor devices that, depending on the particular application, can be either Thermoelectric Coolers (TECs) or Thermoelectric Generators (TEGs). TECs are solid state semiconductor devices that utilize the Peltier effect to transfer heat from one side of the device to the other, thereby creating a cooling effect on the cold side of the device. Because the direction of heat transfer is determined by the polarity of an applied voltage, thermoelectric devices can be used generally as temperature controllers. Similarly, TEGs are solid state semiconductor devices that utilize the Seebeck effect to convert heat (i.e., a temperature difference from one side of the device to the other) directly into electrical energy. A thermoelectric device includes at least one N-type leg and at least one P-type leg. The N-type legs and the P-type legs are formed of a thermoelectric material (i.e., a semiconductor material having sufficiently strong thermoelectric properties). In order to effect thermoelectric cooling, an electrical current is applied to the thermoelectric device. The direction of current transference in the N-type legs and the P-type legs is parallel to the direction of heat transference in the thermoelectric device. As a result, cooling occurs at the top surface of the thermoelectric device, and the heat is released at the bottom surface of the thermoelectric device.

Thermoelectric systems that use thermoelectric devices are advantageous compared to non-thermoelectric systems because they lack moving mechanical parts, have long lifespans, and can have small sizes and flexible shapes. However, there remains a need for thermoelectric devices with increased performance and longer lifespans.

Thin film thermoelectric devices are typically much smaller and more fragile than comparable bulk-type thermoelectric modules. An area for a typical thin film thermoelectric device is on the order of 140 square millimeters (mm²), whereas an area of a typical bulk-type thermoelectric module is on the order of 1,600 mm². Thin film thermoelectric devices can be disposed between heat sinks to form a thermoelectric heat exchanger. A thermal resistance of a thermal interface material between a thermoelectric device and an attached heat sink is defined as I/kA, where I is a thickness of the thermal interface material, k is a thermal conductivity of the thermal interface material, and A is an area of an interface between the thermoelectric device and the heat sink. This means that the thermal resistance of the thermal interface material between a thin film thermoelectric device and a heat sink is on the order of 10 times higher than the thermal resistance of the thermal interface material between a larger bulk-type thermoelectric module and a corresponding heat sink. For thin film thermoelectric devices and, in particular, thin film thermoelectric coolers, the higher thermal resistance of the thermal interface material results in a higher hot side temperature and requires a lower cold side temperature, which leads to higher power consumption and/or inability to cool adequately.

In addition, given their dimensions and material set, thin film thermoelectric devices cannot withstand as much mechanical loading as bulk-type thermoelectric modules. Further, thin film thermoelectric devices cannot withstand uneven mechanical loading. However, heat sinks attached to both sides of thin film thermoelectric devices tend to be quite large compared to the thin film thermoelectric devices and are often constrained in a given product. As such, it is difficult to get even, controlled loading on a thin film thermoelectric device.

Therefore, there is a need for systems and methods for minimizing the thermal resistance of the thermal interface material between thin film thermoelectric devices while also protecting the thin film thermoelectric devices from mechanical loading.

### SUMMARY

A metal core thermoelectric device and a method of manufacturing such a device are provided herein. In some embodiments, a thermoelectric heat exchanger component includes a metal core circuit board and thermoelectric legs that are attached to the metal core circuit board. A top header is attached to the thermoelectric legs opposite the metal core circuit board. A top heat spreading lid is thermally connected to the top header. In this way, the thermoelectric heat exchanger component does not need the bottom header, bottom side Thermal Interface Material (TIM), bottom side attach material, and/or bottom heat spreading lid. This may result in a significant reduction in materials and/or the processing steps required to create the thermoelectric heat exchanger component being greatly simplified. In some embodiments, at least some steps of the manufacturing may use standard surface mount technology equipment.

In some embodiments, the thermoelectric heat exchanger component also includes a TIM between the top header and the top heat spreading lid. In some embodiments, the TIM is solder or thermal grease.

In some embodiments, the thermoelectric heat exchanger component also includes an attach material between the top heat spreading lid and metal core circuit board. In some embodiments, the attach material between the top heat spreading lid and metal core circuit board is an epoxy and/or a resin. In some embodiments, the attach material between the top heat spreading lid and metal core circuit board is able to absorb force applied to the top heat spreading lid so as to protect the plurality of thermoelectric legs. In some embodiments, the attach material between the top heat spreading lid and metal core circuit board provides a hermetic seal between the top heat spreading lid and metal core circuit board to protect the plurality of thermoelectric legs.

In some embodiments, the metal core circuit board includes a metal core layer; a dielectric layer attached to the metal core layer; and an electrically conducting layer attached to the dielectric layer opposite the metal core layer.

In some embodiments, the metal core layer of the metal core circuit board is aluminum, an alloy of aluminum, copper, or an alloy of copper. In some embodiments, the dielectric layer of the metal core circuit board is a dielectric polymer layer with high thermal conductivity.

In some embodiments, a method of fabricating a thermoelectric heat exchanger component includes assembling a top header and a metal core circuit board to thermoelectric legs and attaching the top header with the thermoelectric legs to a top heat spreading lid.

In some embodiments, the method of fabricating the thermoelectric heat exchanger component also includes applying a TIM between the top header and the top heat spreading lid. In some embodiments, the TIM is solder or thermal grease.

In some embodiments, the method of fabricating the thermoelectric heat exchanger component also includes applying an attach material between the top heat spreading lid and the metal core circuit board. In some embodiments, the attach material is an epoxy and/or a resin. In some embodiments, the attach material between the top heat spreading lid and metal core circuit board is able to absorb force applied to the top heat spreading lid so as to protect the thermoelectric legs. In some embodiments, the attach material between the top heat spreading lid and metal core circuit board provides a hermetic seal between the top heat spreading lid and metal core circuit board to protect the thermoelectric legs.

In some embodiments, the metal core circuit board includes a metal core layer; a dielectric layer attached to the metal core layer; and an electrically conducting layer attached to the dielectric layer opposite the metal core layer.

In some embodiments, the metal core layer of the metal core circuit board is aluminum, an alloy of aluminum, copper, or an alloy of copper. In some embodiments, the dielectric layer of the metal core circuit board is a dielectric polymer layer with high thermal conductivity.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a thermoelectric refrigeration system having a cooling chamber, a heat exchanger including at least one Thermoelectric Module (TEM) disposed between a cold side heat sink and a hot side heat sink, and a controller that controls the TEM according to some embodiments of the present disclosure;

FIG. 2 illustrates a side view of a Thermoelectric Component (TEC);

FIG. 3 illustrates a side view of a thermoelectric heat exchanger module;

FIG. 4 illustrates an existing process flow for manufacturing a thermoelectric heat exchanger module as shown in FIG. 3;

FIG. 5 illustrates a side view of a thermoelectric module with a metal core circuit board; and

FIG. 6 illustrates a new process flow according to one embodiment of the present disclosure for manufacturing a thermoelectric heat exchanger module as shown in FIG. 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

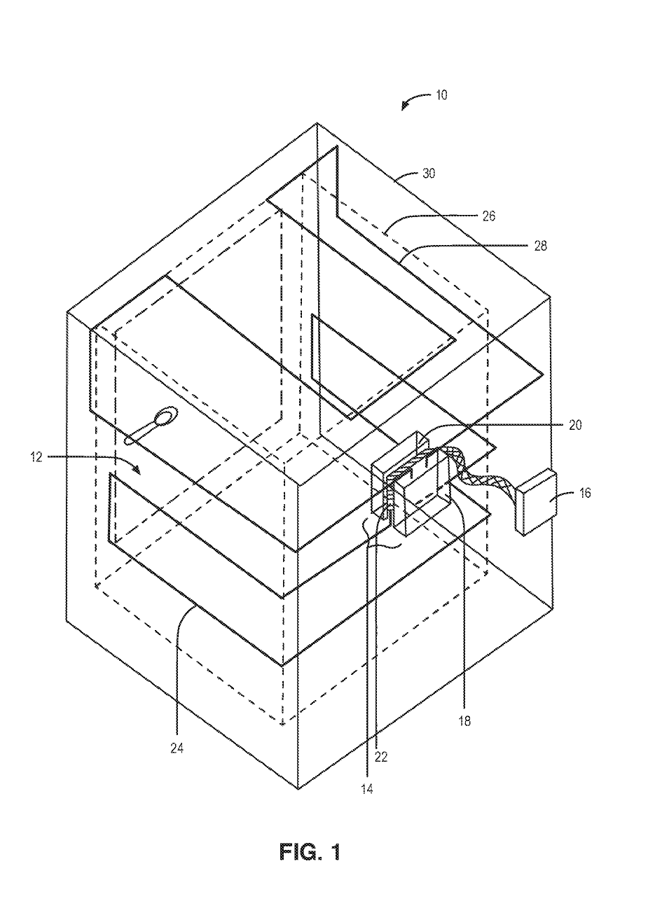

FIG. 1 illustrates a thermoelectric refrigeration system 10 having a cooling chamber 12, a heat exchanger 14 including at least one Thermoelectric Module (TEM) 22 (referred to herein singularly as TEM 22 or plural as TEMs 22) disposed between a cold side heat sink 20 and a hot side heat sink 18, and a controller 16 that controls the TEM 22 according to some embodiments of the present disclosure. When a TEM 22 is used to provide cooling it may sometimes be referred to as a Thermoelectric Cooler (TEC) 22.

The TEMs 22 are preferably thin film devices. When one or more of the TEMs 22 are activated by the controller 16, the activated TEMs 22 operate to heat the hot side heat sink 18 and cool the cold side heat sink 20 to thereby facilitate heat transfer to extract heat from the cooling chamber 12. More specifically, when one or more of the TEMs 22 are activated, the hot side heat sink 18 is heated to thereby create an evaporator and the cold side heat sink 20 is cooled to thereby create a condenser, according to some embodiments of the current disclosure.

Acting as a condenser, the cold side heat sink 20 facilitates heat extraction from the cooling chamber 12 via an accept loop 24 coupled with the cold side heat sink 20. The accept loop 24 is thermally coupled to an interior wall 26 of the thermoelectric refrigeration system 10. The interior wall 26 defines the cooling chamber 12. In one embodiment, the accept loop 24 is either integrated into the interior wall 26 or integrated directly onto the surface of the interior wall 26. The accept loop 24 is formed by any type of plumbing that allows for a cooling medium (e.g., a two-phase coolant) to flow or pass through the accept loop 24. Due to the thermal coupling of the accept loop 24 and the interior wall 26, the cooling medium extracts heat from the cooling chamber 12 as the cooling medium flows through the accept loop 24. The accept loop 24 may be formed of, for example, copper tubing, plastic tubing, stainless steel tubing, aluminum tubing, or the like.

Acting as an evaporator, the hot side heat sink 18 facilitates rejection of heat to an environment external to the cooling chamber 12 via a reject loop 28 coupled to the hot side heat sink 18. The reject loop 28 is thermally coupled to an outer wall 30, or outer skin, of the thermoelectric refrigeration system 10.

The thermal and mechanical processes for removing heat from the cooling chamber 12 are not discussed further. Also, it should be noted that the thermoelectric refrigeration system 10 shown in FIG. 1 is only a particular embodiment of a use and control of a TEM 22. All embodiments discussed herein should be understood to apply to thermoelectric refrigeration system 10 as well as any other use of a TEM 22.

Continuing with the example embodiment illustrated in FIG. 1, the controller 16 operates to control the TEMs 22 in order to maintain a desired set point temperature within the cooling chamber 12. In general, the controller 16 operates to selectively activate/deactivate the TEMs 22, selectively control an amount of power provided to the TEMs 22, and/or selectively control a duty cycle of the TEMs 22 to maintain the desired set point temperature. Further, in preferred embodiments, the controller 16 is enabled to separately or independently control one or more and, in some embodiments, two or more subsets of the TEMs 22, where each subset includes one or more different TEMs 22. Thus, as an example, if there are four TEMs 22, the controller 16 may be enabled to separately control a first individual TEM 22, a second individual TEM 22, and a group of two TEMs 22. By this method, the controller 16 can, for example, selectively activate one, two, three, or four TEMs 22 independently, at maximized efficiency, as demand dictates.

It should be noted that the thermoelectric refrigeration system 10 is only an example implementation and that the systems and methods disclosed herein are applicable to other uses of thermoelectric devices as well.

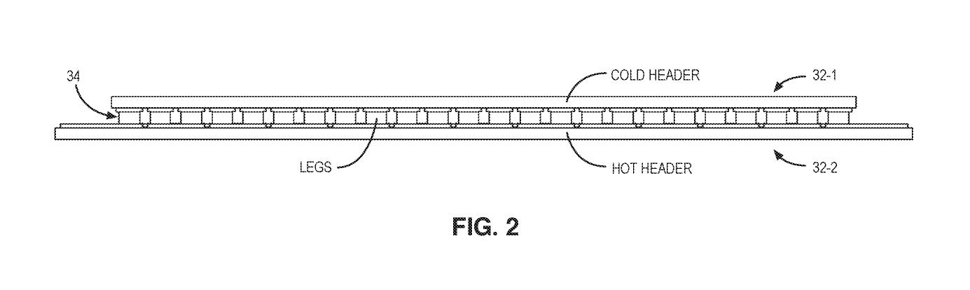

A common thermoelectric device such as a TEM 22 is shown in FIG. 2. The thermoelectric device consists of two headers 32, commonly referred to as cold header 32-1 and a hot header 32-2, and a series of legs 34 that are soldered to each header. In some embodiments, the headers 32 are made of ceramic. When the thermoelectric device is operated, heat is moved from the cold header 32-1 to the hot header 32-2, causing a temperature difference between the headers 32. This temperature difference results in thermal expansion and contraction of each header.

There is a need for systems and methods for minimizing the thermal resistance of the thermal interface material between thin film thermoelectric devices while also protecting the thin film thermoelectric devices from mechanical loading.

U.S. Pat. No. 8,893,513, the disclosure of which is hereby incorporated herein by reference in its entirety, details a method to encapsulate multiple thermoelectric devices on a circuit board with protective heat spreading lids and optimal thermal interface resistance. Although the method is advantageous for various applications, the design requires multiple interfaces and components.

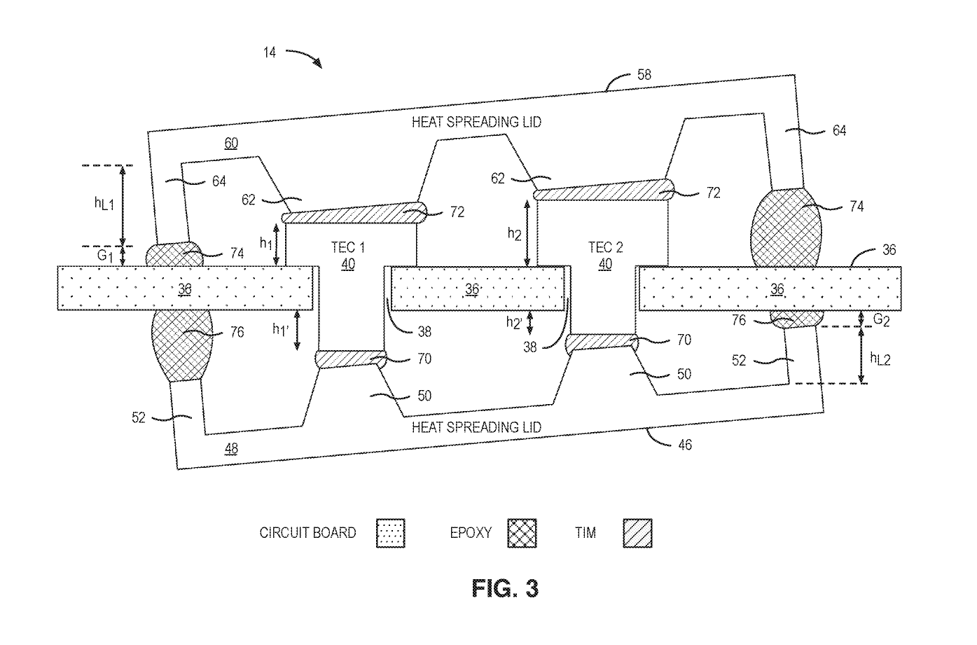

FIG. 3 illustrates a side view of a thermoelectric heat exchanger module such as heat exchanger 14 shown in FIG. 1. Heat spreading lids 46 and 58 enable the thermal interface resistance at the interfaces between the heat spreading lids 46 and 58 and TECs 40 to be optimized. More specifically, as illustrated in FIG. 3, heights of two or more of the TECs 40 may vary. Using conventional techniques to attach the TECs 40 to the hot side and/or the cold side heat sinks 18 and 20 would result in a less than optimal thermal interface resistance for shorter TECs 40 because there would be a larger amount of thermal interface material between those shorter TECs 40 and the corresponding heat sink 18, 20. In contrast, the structure of the heat spreading lids 46 and 58 enable an orientation (i.e., tilt) of the heat spreading lids 46 and 58 to be adjusted to optimize the thickness of Thermal Interface Material (TIM) 70, 72, and thus the thermal interface resistance, between pedestals 50, 62 and the corresponding surfaces of the TECs 40.

In this example, TEC 1 has a height (h₁) relative to the first surface of a circuit board 36 that is less than a height (h₂) of TEC 2 relative to the first surface of the circuit board 36. As discussed below in detail, when the heat spreading lid 58 is positioned over the TECs 40, a ball point force (i.e., a force applied via a ball point) is applied to a center of the heat spreading lid 58. As a result, the heat spreading lid 58 settles at an orientation that optimizes a thickness of the thermal interface material 72 between each of the pedestals 62 and the corresponding TEC 40.

A height (h_{L1}) of a lip 64 of the heat spreading lid 58 is such that, for any possible combination of heights (h₁ and h₂) with a predefined tolerance range for the heights of the TECs 40 relative to the first surface of the circuit board 36, a gap (G₁) between the lip 64 and the circuit board 36 is greater than a predefined minimum gap. The predefined minimum gap is a non-zero value. In one particular embodiment, the predefined minimum gap is a minimum gap needed for an epoxy and/or resin 74 to fill the gap (G₁) while maintaining a predefined amount of pressure or force between the heat spreading lid 58 and TECs 40. Specifically, the height (hp) of the lip 64 is greater than a minimum possible height of the TECs 40 relative to the first surface of the circuit board 36 plus the height of the pedestals 62, plus a predefined minimum height of the thermal interface material 72, plus some additional value that is a function of a maximum possible angle of the heat spreading lid 58 (which is a function of the minimum and maximum possible heights of the TECs 40) and a distance between the lip 64 and the nearest pedestal 62. In this embodiment, by adjusting the orientation of the heat spreading lid 58, the thickness of the thermal interface material 72, and thus the thermal interface resistance, for each of the TECs 40 is minimized.

In a similar manner, TEC 1 has a height (h₁′) relative to the second surface of the circuit board 36 that is greater than a height (h₂′) of TEC 2 relative to the second surface of the circuit board 36. As discussed below in detail, when the heat spreading lid 46 is positioned over the TECs 40, a ball point force (i.e., a force applied via a ball point) is applied to a center of the heat spreading lid 46. As a result, the heat spreading lid 46 settles at an orientation that optimizes a thickness of the thermal interface material 70 between each of the pedestals 50 and the corresponding TEC 40.

A height (h_{L2}) of a lip 52 of the heat spreading lid 46 is such that, for any possible combination of heights (h₁′ and h₂′) with a predefined tolerance range for the heights of the TECs 40 relative to the second surface of the circuit board 36, a gap (G₂) between the lip 52 and the circuit board 36 is greater than a predefined minimum gap. The predefined minimum gap is a non-zero value. In one particular embodiment, the predefined minimum gap is a minimum gap needed for an epoxy and/or resin 76 to fill the gap (G₂) while maintaining a predefined amount of pressure or force between the heat spreading lid 46 and TECs 40. Specifically, the height (h_{L2}) of the lip 52 is greater than a minimum possible height of the TECs 40 relative to the second surface of the circuit board 36 plus the height of the pedestals 50, plus a predefined minimum height of the thermal interface material 70, plus some additional value that is a function of a maximum possible angle of the heat spreading lid 46 (which is a function of the minimum and maximum possible heights of the TECs 40) and a distance between the lip 52 and the nearest pedestal 50. In this embodiment, by adjusting the orientation of the heat spreading lid 46, the thickness of the thermal interface material 70, and thus the thermal interface resistance, for each of the TECs 40 is minimized.

In the embodiment of FIG. 3, the dimensions of the pedestals 50 and 62 are slightly less than the dimensions of the corresponding surfaces of the TECs 40 at the interfaces between the pedestals 50 and 62 and the corresponding surfaces of the TECs 40. As such, when applying the ball point force to the heat spreading lids 46 and 58, the excess thermal interface material 70 and 72 moves along the edges of the pedestals 50 and 62 and is thereby prevented from thermally shorting the legs of the TECs 40. It should also be pointed out that any force applied to the heat spreading lid 46 is absorbed by the lip 52, the epoxy and/or resin 76, and the circuit board 36, which thereby protects the TECs 40. Likewise, any force applied to the heat spreading lid 58 is absorbed by the lip 64, the epoxy and/or resin 74, and the circuit board 36, which thereby protects the TECs 40. In this manner, significantly more even and uneven forces can be applied to the thermoelectric heat exchanger component 14 without damaging the TECs 40 as compared to a comparable heat exchanger component without the heat spreading lids 46 and 58.

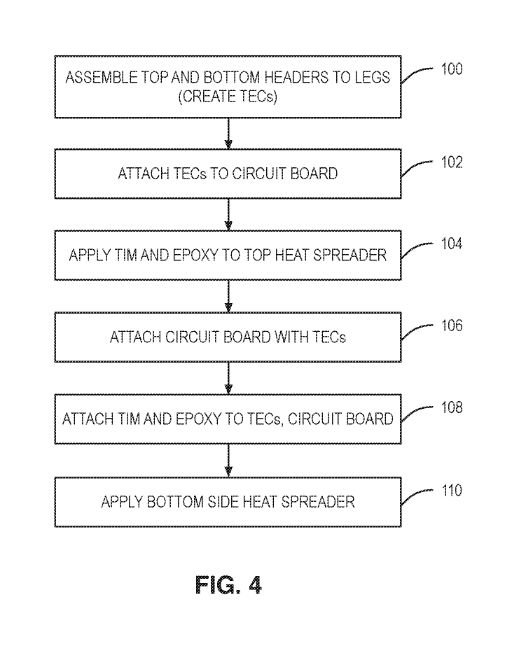

FIG. 4 illustrates an example of an existing process flow for manufacturing a thermoelectric heat exchanger module as shown in FIG. 3. First, the top and bottom headers must be assembled with the thermoelectric legs to produce the TECs 40 (step 100). As illustrated, the TECs 40 are then attached to the circuit board 36 (step 102). As discussed in the example above, the TECs 40 may be attached to the circuit board 36 over the holes 38 in the circuit board 36 such that bottom surfaces of the TECs 40, which are preferably the less critical or cold sides of the TECs 40, are exposed through the holes 38. The TECs 40 are attached to the circuit board 36 using any suitable electrically conductive material such as, for example, solder. In addition, the TIM 70, 72 is applied to the pedestals 50, 62 of the heat spreading lid 46, 58 and/or the appropriate surfaces of the TECs 40 and epoxy and/or resin is applied to the top heat spreader (step 104). For example, a thermal grease, or thermal paste, may be screen printed on the surfaces of the pedestals 50, 62.

Next, the circuit board 36 with the corresponding TECs 40 is attached (step 106). TIM and epoxy and/or resin are applied to the bottom side of the TECs 40 and circuit board 36 (step 108). Lastly, the bottom side heat spreader 46 is attached to the epoxy and/or resin 76 and the TIM 70 (step 110).

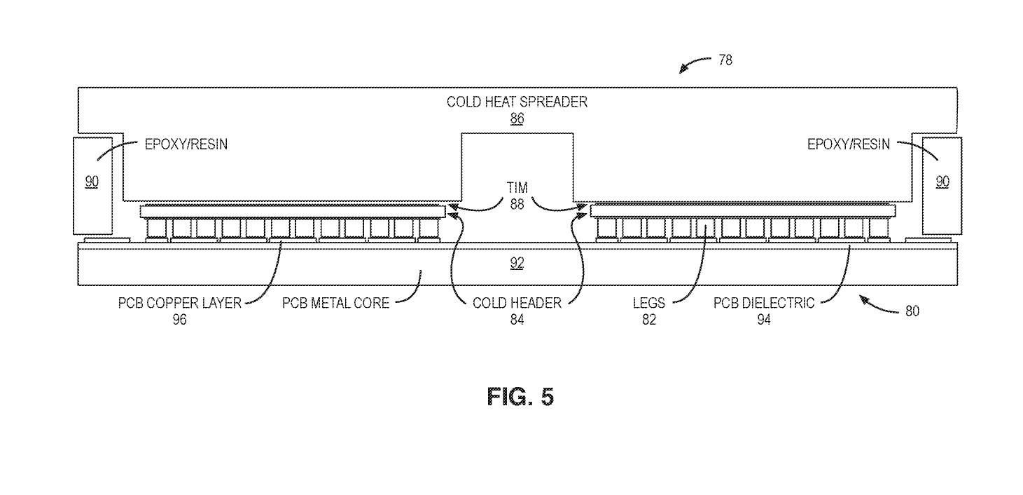

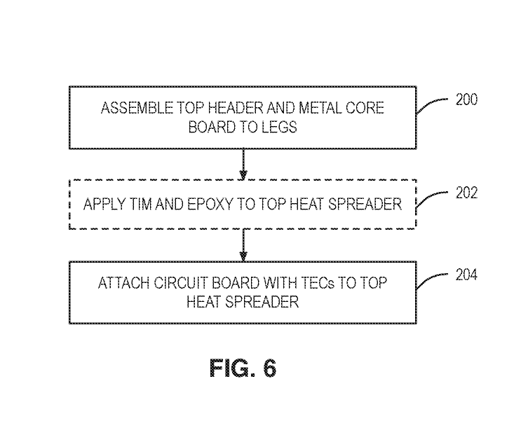

An alternate approach to obtain the benefits of U.S. Pat. No. 8,893,513 can be realized with fewer materials and processing steps without sacrificing the exchanger module benefits. FIGS. 5 and 6 outline an approach using a base metal core circuit board as the base of the TECs and the bottom heat spreader lid.

A metal core thermoelectric device and a method of manufacturing such a device are provided herein. In some embodiments, a thermoelectric heat exchanger component includes a metal core circuit board and thermoelectric legs that are attached to the metal core circuit board. A top header is attached to the thermoelectric legs opposite the metal core circuit board. A top heat spreading lid is thermally connected to the top header. In this way, the thermoelectric heat exchanger component does not need the bottom header, bottom side TIM, bottom side attach material, and/or bottom heat spreading lid. This may result in a significant reduction in materials and/or the processing steps required to create the thermoelectric heat exchanger component being greatly simplified. In some embodiments, at least some steps of the manufacturing may use standard surface mount technology equipment.

FIG. 5 illustrates a side view of a thermoelectric module with a metal core circuit board. As shown, a thermoelectric heat exchanger component 78 includes a metal core circuit board 80 and multiple thermoelectric legs 82 that are attached to the metal core circuit board 80. The thermoelectric heat exchanger component 78 also includes a top header 84 attached to the thermoelectric legs 82 opposite the metal core circuit board 80. The thermoelectric heat exchanger component 78 also includes a top heat spreading lid 86 thermally connected to the top header 84.

In some embodiments, the thermoelectric heat exchanger component 78 also includes a TIM 88 between the top header 84 and the top heat spreading lid 86. In some embodiments, the TIM 88 is solder or thermal grease as discussed above.

In some embodiments, the thermoelectric heat exchanger component 78 also includes an attach material 90 between the top heat spreading lid 86 and metal core circuit board 80. In some embodiments, the attach material 90 between the top heat spreading lid 86 and metal core circuit board 80 is an epoxy and/or a resin. In some embodiments, the attach material 90 between the top heat spreading lid 86 and metal core circuit board 80 is able to absorb force applied to the top heat spreading lid 86 so as to protect the thermoelectric legs 82. In some embodiments, the attach material 90 between the top heat spreading lid 86 and the metal core circuit board 80 provides a hermetic seal between the top heat spreading lid 86 and the metal core circuit board to protect the thermoelectric legs 82.

In some embodiments, the metal core circuit board 80 includes a metal core layer 92; a dielectric layer 94 attached to the metal core layer 92; and an electrically conducting layer 96 attached to the dielectric layer 94 opposite the metal core layer 92.

In some embodiments, the metal core layer 92 of the metal core circuit board 80 is aluminum, an alloy of aluminum, copper, or an alloy of copper. In some embodiments, the dielectric layer 94 of the metal core circuit board 80 is a dielectric polymer layer with high thermal conductivity.

As shown in FIG. 5, the metal core circuit board 80 can replace the TEC hot header, bottom side TIM, bottom side epoxy and/or resin, and bottom heat spreading lid that was required for the thermoelectric heat exchanger module as shown in FIG. 3. Not only is this a significant reduction in materials, but the processing steps required to create the thermoelectric heat exchanger component 78 are greatly simplified using standard surface mount technology equipment.

FIG. 6 illustrates a new process flow according to one embodiment of the present disclosure for manufacturing the thermoelectric heat exchanger component 78 as shown in FIG. 5. The method includes assembling a top header 84 and a metal core circuit board 80 to thermoelectric legs 82 (step 200).

In some embodiments, the method of fabricating the thermoelectric heat exchanger component 78 optionally includes applying a TIM 88 between the top header 84 and the top heat spreading lid 86 (step 202). The method may also optionally include applying an attach material 90 between the top heat spreading lid 86 and the metal core circuit board 80 (step 202). As discussed above, the TIM 88 is solder or thermal grease and the attach material 90 between the top heat spreading lid 86 and metal core circuit board 80 is an epoxy and/or a resin. In some embodiments, the attach material 90 between the top heat spreading lid 86 and metal core circuit board 80 is able to absorb force applied to the top heat spreading lid 86 so as to protect the thermoelectric legs 82. In some embodiments, the attach material 90 between the top heat spreading lid 86 and the metal core circuit board 80 provides a hermetic seal between the top heat spreading lid 86 and the metal core circuit board to protect the thermoelectric legs 82.

The method of fabricating the thermoelectric heat exchanger component 78 also includes attaching the top header 84 with the thermoelectric legs 82 to a top heat spreading lid 86 (step 204). In this way, a thermoelectric heat exchanger component 78 can be manufactured where the thermoelectric heat exchanger component 78 does not need the bottom header, bottom side TIM, bottom side attach material, and/or bottom heat spreading lid. This may result in a significant reduction in materials and/or the processing steps required to create the thermoelectric heat exchanger component being greatly simplified. In some embodiments, at least some steps of the manufacturing may use standard surface mount technology equipment.

Those skilled in the art will recognize improvements and modifications to the preferred embodiments of the present disclosure. All such improvements and modifications are considered within the scope of the concepts disclosed herein and the claims that follow.

What is claimed is:

1. A thermoelectric heat exchanger component, comprising:
a metal core circuit board;
a plurality of thermoelectric legs that are attached to the metal core circuit board;
a top header attached to the plurality of thermoelectric legs opposite the metal core circuit board; and
a top heat spreading lid thermally connected to the top header.

2. The thermoelectric heat exchanger component of claim 1 further comprising:
a thermal interface material between the top header and the top heat spreading lid.

3. The thermoelectric heat exchanger component of claim 2 wherein the thermal interface material is chosen from the group consisting of: solder and thermal grease.

4. The thermoelectric heat exchanger component of claim 3 further comprising:
an attach material between the top heat spreading lid and the metal core circuit board.

5. The thermoelectric heat exchanger component of claim 4 wherein the attach material between the top heat spreading lid and the metal core circuit board is chosen from the group consisting of: an epoxy and a resin.

6. The thermoelectric heat exchanger component of claim 5 wherein the attach material between the top heat spreading lid and the metal core circuit board is able to absorb force applied to the top heat spreading lid so as to protect the plurality of thermoelectric legs.

7. The thermoelectric heat exchanger component of claim 6 wherein the attach material between the top heat spreading lid and metal core circuit board provides a hermetic seal between the top heat spreading lid and metal core circuit board to protect the plurality of thermoelectric legs.

8. The thermoelectric heat exchanger component of claim 7 wherein the metal core circuit board comprises:
a metal core layer;
a dielectric layer attached to the metal core layer; and
an electrically conducting layer attached to the dielectric layer opposite the metal core layer.

9. The thermoelectric heat exchanger component of claim 8 wherein the metal core layer of the metal core circuit board is chosen from the group consisting of: aluminum and an alloy of aluminum.

10. The thermoelectric heat exchanger component of claim 8 wherein the metal core layer of the metal core circuit board is chosen from the group consisting of: copper and an alloy of copper.

11. The thermoelectric heat exchanger component of claim 10 wherein the dielectric layer of the metal core circuit board is a dielectric polymer layer with high thermal conductivity.

12. A method of fabricating a thermoelectric heat exchanger component, comprising:
assembling a top header and a metal core circuit board to a plurality of thermoelectric legs; and
attaching the top header with the plurality of thermoelectric legs to a top heat spreading lid.

13. The method of fabricating the thermoelectric heat exchanger component of claim 12 further comprising:
applying a thermal interface material between the top header and the top heat spreading lid.

14. The method of fabricating the thermoelectric heat exchanger component of claim 13 wherein applying the thermal interface comprises applying a material chosen from the group consisting of: solder and thermal grease.

15. The method of fabricating the thermoelectric heat exchanger component claim 14 further comprising:
applying an attach material between the top heat spreading lid and the metal core circuit board.

16. The method of fabricating the thermoelectric heat exchanger component of claim 15 wherein applying the attach material between the top heat spreading lid and the metal core circuit board comprises applying a material chosen from the group consisting of: an epoxy and a resin.

17. The method of fabricating the thermoelectric heat exchanger component of claim 16 wherein the attach material between the top heat spreading lid and the metal core circuit board is able to absorb force applied to the top heat spreading lid so as to protect the plurality of thermoelectric legs.

18. The method of fabricating the thermoelectric heat exchanger component of claim 17 wherein the attach material between the top heat spreading lid and metal core circuit board provides a hermetic seal between the top heat spreading lid and the metal core circuit board to protect the plurality of thermoelectric legs.

19. The method of fabricating the thermoelectric heat exchanger component of claim 18 wherein the metal core circuit board comprises:
a metal core layer;
a dielectric layer attached to the metal core layer; and
an electrically conducting layer attached to the dielectric layer opposite the metal core layer.

20. The method of fabricating the thermoelectric heat exchanger component of claim 19 wherein the metal core layer of the metal core circuit board is chosen from the group consisting of: aluminum and an alloy of aluminum.

21. The method of fabricating the thermoelectric heat exchanger component of claim 19 wherein the metal core layer of the metal core circuit board is chosen from the group consisting of: copper and an alloy of copper.

22. The method of fabricating the thermoelectric heat exchanger component of claim 21 wherein the dielectric layer of the metal core circuit board is a dielectric polymer layer with high thermal conductivity.
